(19) United States
(12) Patent Application Publication
(10) Pub. No.: US 2013/0335351 A1
(43) Pub. Date: Dec. 19, 2013

(54) MODELING PIEZOS FOR MINIMIZED POWER CONSUMPTION AND MAXIMIZED TACTILE DETECTION ON A HAPTIC DISPLAY

(71) Applicants: KOC UNIVERSITESI, Istanbul (TR); TURK TELEKOMUNIKASYON A.S., Ankara (TR)

(72) Inventors: Arda AKMAN, Ankara (TR); Cebrail TASKIN, Ankara (TR); Enis ERKEL, Ankara (TR); Cagatay BASDOGAN, Istanbul (TR)

(21) Appl. No.: 13/902,547

(22) Filed: May 24, 2013

(30) Foreign Application Priority Data
May 25, 2012 (TR) 2012/06132

(51) Int. Cl. G06F 3/01; H01L 41/09

(52) U.S. Cl. CPC G06F 3/016; H01L 41/09
USPC 345/173

(57) ABSTRACT

A haptic display with a touch screen surface enabled to be tactically detectable by the addition of a thin-film piezo stimulator thereto is disclosed. A modeling for minimized power consumption and a maximized tactile detection on the display is also disclosed. The haptic screen, during operation of a touch screen, enables a user to have a haptic interaction with the screen through vibrations generated on the touch surface. A piezo placement model enables to achieve vibrations of specific values at each spot on the screen where the user touches, through the use of a minimum number of piezo components of the screen so as to provide an optimum tactile detection and minimum power consumption. Pre-defined values of amplitude and frequency are applied to ensure that the vibration is detected in accordance with the placement model and pre-defined values of the placement model are used depending on the position of touch.

### FIELD OF INVENTION

This invention relates to a haptic display with a touch screen surface rendered tactically detectable by the addition of a thin-film piezo stimulator thereto and to a modeling for minimized power consumption and a maximized tactile detection on the said display.

### PRIOR ART

Thanks to the flexibility created by the touch screen devices particularly on the keyboards and keypads, many devices have become usable via a number of screens. The touch screens that enable the users both to display the data on screen and also to input data have a large number of varied structures of detection. However, during the said interactions the user just moves his fingers over a smooth screen surface having no haptic effect. There are a number of patent applications in the literature in order to eliminate this drawback, so that the users can control the screens via a haptic effect.

The objective of the studies on haptic screens is to reflect a screen response on fingers, which response is usually in harmony with the figures, designs, colors or movements shown on the display. Both vision and touch senses of a user can be stimulated simultaneously by creating an effect for an image of protuberance or texture that is different than that created for another image.

The stimulators used on haptic screens to create a haptic effect, comprise some variations, for example in terms of the method of image generation. Small vibrations that can be detected by fingers based on the said stimulators can be generated by vibration motors, masses that vibrate under electric field or by piezo crystals. It is also possible to change the character of the virtual surface texture detected by the fingers by changing the frequency or amplitude of vibration.

European patent application no. EP2273799A1 discloses an example of prior art haptic screens. Piezos are arranged at each of the 4 corners of display to vibrate it depending on the interaction between the user and the objects on display. The vibrations on the display in specific frequency ranges ensure that the fingers feel moving over a rough surface on the display.

Another example of the prior art devices is disclosed in the United States patent application no. US2011090070A1 which describes an embodiment used for generating vibrations with variable frequencies. This embodiment ensures that the vibrations generated by piezo crystals have different frequencies.

### BRIEF DESCRIPTION OF INVENTION

An objective of this invention is to develop a haptic screen that, during operation of a touch screen, enables a user to have a tactile detection/haptic interaction with the screen through vibrations generated on the touch surface.

The vibrations generated on the haptic screens by the equipment used, would generate a wave on the touch surface that is a restricted field. This wave would fade either at the nodes or at each period of the respective wave when it is vibrated within a restricted field. A finger would not feel any vibrations if it touches the spots of fading on the screen. However, it is essential that a user is able to interact with each spot on the screen and that the vibrations of variable frequencies and amplitudes are generated at each spot on the screen.

Vibrations are provided by those equipment which ensure that an electrical action finds its corresponding physical response and their power should be increased in proportion with the sizes of vibrated screen. The amount of energy they consume is higher than the consumed energy of any other electronic components both due to the screen sizes and also due to the fact that they would generate a mechanical action.

The first of the needs as listed hereabove, i.e. the need to generate vibrations of variable amplitudes at each spot on the screen and the optimum placement to achieve low consumption values are the most significant needs on a haptic screen. Therefore, the invention aims to develop such piezo placement models that enable to achieve vibrations of specific values at each spot on the screen touched by the user, through the use of a minimum number of piezo components of the said screen. Furthermore, another object of the present invention is to apply such amplitude and frequency values that are required to ensure that the vibration is detected in accordance with the placement models and the pre-defined values of the placement model used depending on the position of the user's touch, in such a way to achieve an optimum tactile detection and a minimum power consumption.

In order to realize these objectives, the screen size-specific frequencies will be determined. However, once the optimum values of a used placement model are generated particularly for a specific screen size, the mathematical model will be developed in the scope of the present invention in order to apply the same model to any other screens in different sizes.

### DETAILED DESCRIPTION OF INVENTION

The haptic screen realized for the achievement of the objectives of the invention is illustrated in the drawings attached, in which

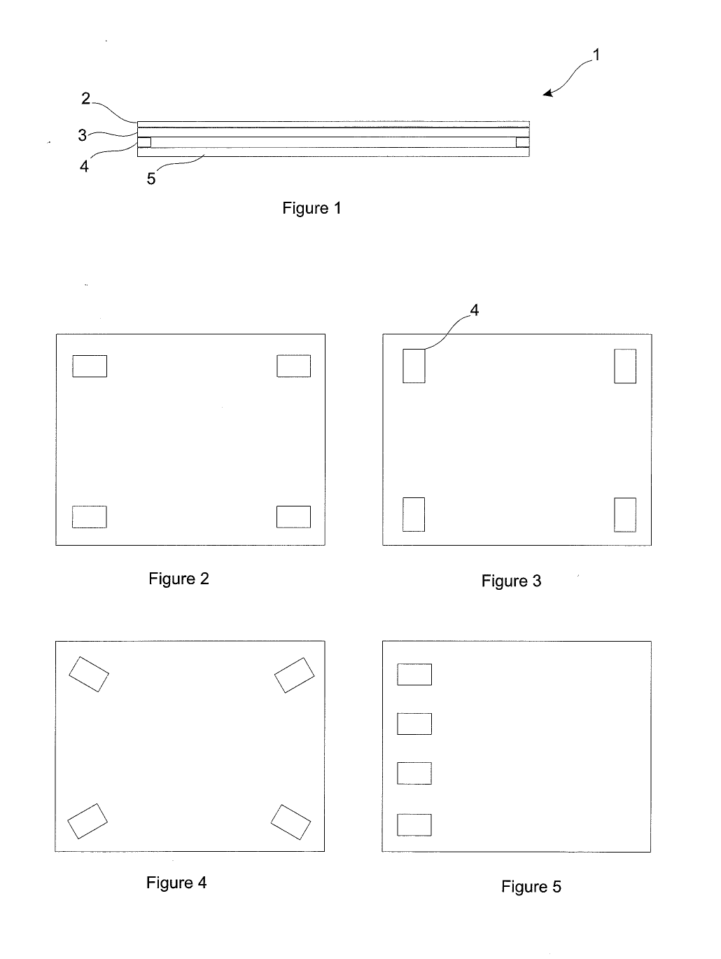

FIG. 1—is a schematic illustration of the cross-section of the haptic screen of the present invention.

FIG. 2—is a schematic view of the horizontally-oriented placement model of piezos attached to the glass of the haptic screen of the present invention.

FIG. 3—is a schematic view of the vertically-oriented corner placement model of piezos attached to the glass of the haptic screen of the present invention.

FIG. 4—is a schematic view of the crosswise-oriented corner placement model of piezos attached to the glass of the haptic screen of the present invention.

FIG. 5—is a schematic view of the horizontally-oriented side placement model of piezos attached to the glass of the haptic screen of the present invention.

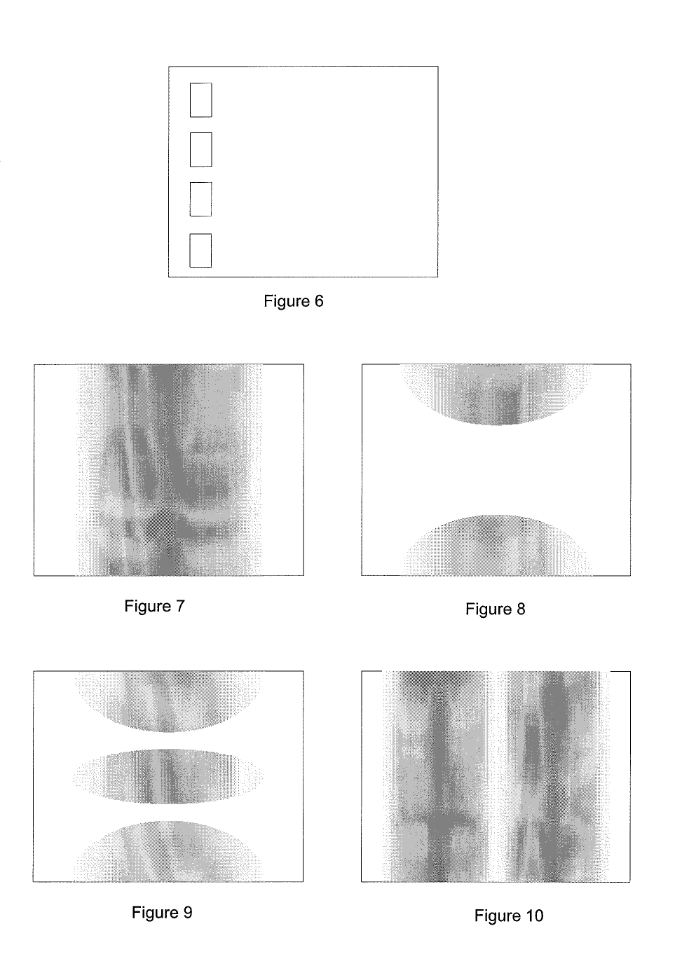

FIG. 6—is a schematic view of the vertically-oriented side placement model of piezos attached to the glass of the haptic screen of the present invention.

FIG. 7—is a schematic view of the resonance model created by the piezos that are fixed at both sides to the glass of the haptic screen of the present invention and that vibrate at 321.38 Hz.

FIG. 8—is a schematic view of the resonance model created by the piezos that are fixed at both sides to the glass of the haptic screen of the present invention and vibrate at 418.52 Hz.

FIG. 9—is a schematic view of the resonance model created by the piezos that are fixed at both sides to the glass of the haptic screen of the present invention and vibrate at 772.66 Hz.

FIG. 10—is a schematic view of the resonance model created by the piezos that are fixed at both sides to the glass of the haptic screen of the present invention and that vibrate at 964.60 Hz.

The components in the figures are numbered as follows.
1. Haptic screen
2. Detection surface
3. Glass
4. Piezo
5. Display

The inventive haptic screen (1) basically comprises a detection surface (2) that detects the position touched by the user, a glass (3) which is pressed and then vibrated, multiple piezos (4) that ensure vibrations and a display (5). The display (5) may be one of the LCD, LED or OLED which are currently in use in electronic devices. It is also possible to apply the haptic screen (1) of the present invention even to any other displays, including CRT, because it is an adequate property in terms of the application of the present invention that the display (5) shows the image of a key to be clicked on or of an object to be dragged.

In a similar fashion, the detection surface (2) may comprise a resistive, electromagnetic or capacitive film layer disposed either on the display (5) or on a glass (3) present on the display (5). Similarly, through the use of IR frames around the display, it is possible to generate on the display a virtual detection surface (2) which is either IR-coated or similar in the IR frames to ensure determination of the touch spot. The data obtained via any alternative routes hereabove, is the position itself that is actually touched by the user on the display (5).

Haptic screen (1) will enable vibrations on the glass (3) in order to vibrate the touching fingers with a roughness/vibration value assigned to the spot being touched. The vibrations will be achieved by multiple piezos (4) vibrating the glass (3). The glass (3) surface will vibrate in different way at different spots depending on the corresponding frequency and amplitude used at the time of triggering the piezos (4) which are the source of vibration. However, the user desirably feels similar vibration values for similar images on the display.

Therefore, the piezos (4) should be placed around the glass (3) and oriented such that the said similarities are achieved. The said placement models include respectively:
a. the model wherein each of 4 piezos (4) is placed at each corner of the glass (3) in a horizontally oriented fashion,
b. the model wherein each of 4 piezos (4) is placed at each corner of the glass (3) in a vertically oriented fashion,
c. the model wherein each of 4 piezos (4) is placed at each corner of the glass (3) in a crosswise oriented fashion,
d. the model wherein 4 piezos (4) are placed aside the glass (3) in a horizontally oriented fashion.

For each model as listed above, the vibrations generated by the piezos (4) run on an axis that is tangent to the glass (3), but not towards to it. Therefore the piezos (4) should be oriented as required by their inherent characteristics. The piezo (4) placement models are given hereabove as comprising 2 different positioning modes and 3 different orientation modes. 4 piezos (4) in these models are vibrated and thereby a vibration is generated in the largest area possible on the surface of glass (3). But another fact that must be taken into account together with the said placement are the spot or edges, to which the glass (3) is fixed.

In one preferred embodiment of the haptic screen (1) of the present invention, the glass (3) which covers the haptic screen (1) and will be vibrated, is fixed at two sides. The said mode of fixation ensures less vibration at the sides of the glass (3) and it is possible to achieve different resonance values on the display depending on the theoretical values of the resonance model applied. In a preferred embodiment of the invention, the glass (3) of 230×180×1 mm will vibrate, when exposed to applicable frequencies, with a value in proportion to its size.

The said frequencies will be determined as follows through a limited-element model and equation using the glass sizes and mode of fixation of the glass which comprise the boundary condition as mentioned hereabove. The limited-element equation used in these calculations is as follows;

MÜ+KᵤᵤU+K_{uΦ}Φ=F

K_{Φu}U+K_{ΦΦ}Φ=G

wherein in the first equation M refers to mass matrix, Kᵤᵤ refers to stiffness matrix, K_{uΦ} and K_{Φu} refer to piezo electric pair matrixes, K_{ΦΦ} refers to capacitance matrix, U refers to displacement, Φ refers to electrical potential, F refers to force applied externally and G refers to potential load applied. Assuming F being equal to zero since there is no external force;

MÜ+KᵤᵤU+K_{uΦ}Φ=0

MÜ+KᵤᵤU=−K_{uΦ}Φ

and if we solve this equation for Φ;

Φ=K_{ΦΦ}⁻¹[G−K_{uΦ}^{T}U]

and if we apply the product to the equation hereabove, we will obtain the following solution:

MÜ+KᵤᵤU=−K_{uΦ} K_{ΦΦ}⁻¹G+K_{uΦ} K_{ΦΦ}⁻¹K_{uΦ}^{T} U

MÜ+[Kᵤᵤ−K_{uΦ} K_{ΦΦ}⁻¹K_{uΦ}^{T}]U=—K_{uΦ} K_{ΦΦ}⁻¹G

In short, we will obtain the following solution:

MÜ+KU=T_{GΦ}G

K=Kᵤᵤ−K_{uΦ} K_{ΦΦ}⁻¹K_{uΦ}^{T}

T_{GΦ}=−K_{uΦ} K_{ΦΦ}⁻¹

The equation above will give the displacement value obtained in correspondence to the load applied (G). The displacement generated over piezos (4) will reflect on the glass (3). If a sinusoidal current is applied to piezos (4) in the form of G=|G|e^{jωt}, a sinusoidal output will be achieved on glass (3) in a phase-shifted frequency in accordance with U=|U|e^{jωt+Ψ.}

When the corresponding equation is solved to obtain a wavelength over the glass in the range of 0.1-500 Hz which is a wavelength that can be detected by a human hand, 4 different resonance models are achieved. The resonance models herebelow are generated if the piezos (4) located at the corners of a glass (3) of corresponding sizes are vibrated as follows:
using a sinusoidal wave value of 100-120 Hz and preferably 106 Hz, at the central vertical axis,
using a sinusoidal wave value of 130-150 Hz and preferably 140 Hz, at the upper and lower center,
using a sinusoidal wave value of 260-290 Hz and preferably 276 Hz, at the upper center, lower center and in the middle of the glass (3),
using a sinusoidal wave value of 290-320 Hz and preferably 296 Hz, a resonance model that concentrates in the middle of the two halves of glass (3) and fades in the center.

As it can be seen by examining the resonance models given hereabove, at different frequencies vibrations are generated only at a specific part of the glass (3). Also no vibrations are achieved at the spots where the glass (3) is fixed. Therefore, it is possible to ensure that the glass (3) itself is larger than the display (5) and the part of glass (3) that fully covers the display (5) creates a field that can be vibrated completely.

In addition, even if the resonance models achievable with variable frequencies create a vibration at the same spot of a glass (3), the amplitudes that are required to generate the corresponding vibration values vary at different frequencies. In order to reduce the consumption values that the said amplitudes would result in, it is possible to achieve the same glass (3) resonance value with a relative lower amplitude through the use of 106 Hz instead of 276 Hz, if the spot touched by the user is, for instance, in the middle. In a similar case, for any spot located at either side of the glass (3) to be covered by resonance, the piezos (4) can be vibrated at a frequency of 296 Hz instead of 106 Hz.

For a user to feel the same vibrations when changing location by moving this hand over the glass (3), it is possible either to keep feeling the same resonance on the fingers by changing only the amplitude, but not the frequency according to the applicable resonance model or to create the same resonance of a lower amplitude and a different frequency at the relevant spot by vibrating the piezos (4) at the frequency that forms a different resonance model. For this purpose, the piezos (4) of all placement modes will be positioned on the same glass (3) and the piezos (4) will be vibrated so that the highest amplitude will be achieved at any spot on the glass (3) in correspondence to the lowest load (G).

It is possible to make a user feel similar vibrations for similar objects by performing amplitude variations and frequency variations at a frequency value in proportion with the size of glass (3) and in accordance with the location of user's fingers.

1. A haptic screen, for enabling a touch screen surface to be tactically detectable or vibration-simulated, comprising:
a display configured to display an image of a key to be clicked on, of an object to be dragged;
a glass attached at its pressed and vibrated sides and;
a detection surface placed over the glass, which is an IR frame or similar or comprises a resistive, electromagnetic or capacitive film layer;
wherein
four piezos, each placed at a predetermined location of said glass in a predefined orientation and vibrated by a sinusoidal wave of different frequencies as a solution of an applicable equation if a spot touched by a user is on a predetermined location of the glass.

2. A haptic screen as claimed in claim 23, wherein each of said four vibrated piezos is placed at a corner of the glass in a vertical orientation instead of horizontal orientation.

3. A haptic screen as claimed in claim 23, wherein each of said four vibrated piezos is placed at a corner of the glass in a crosswise orientation instead of horizontal orientation.

4. A haptic screen as claimed in claim 23, wherein each of said four vibrated piezos is placed at one side of the glass in said horizontal orientation.

5. A haptic screen as claimed in claim 1, wherein the touch screen is configured to be vibration-simulated, and
wherein
each of said four piezos is placed at a corner of said glass in a horizontal orientation and vibrated by a sinusoidal wave of 130-150 Hz as a solution of an applicable equation if the spot touched by the user is at an upper or in a lower center of said glass.

6. A haptic screen as claimed in claim 5, wherein each of said four vibrated piezos is placed at a corner of said glass in a vertical orientation instead of horizontal orientation.

7. A haptic screen as claimed in claim 5, wherein each of said four vibrated piezos is placed at a corner of said glass in a crosswise orientation instead of horizontal orientation.

8. A haptic screen as claimed in claim 5, wherein each of said vibrated piezos is placed at one side of said glass instead of its corners in said horizontal orientation.

9. A haptic screen as claimed in claim 1, wherein the touch screen surface is configured to be tactically detectable, and wherein
each of said four piezos is placed at a corner of said glass in a horizontal orientation and vibrated by a sinusoidal wave of 260-290 Hz as a solution of an applicable equation if the spot touched by the user is at an upper, lower center or in the middle of the glass.

10. A haptic screen as claimed in claim 9, wherein each of said four vibrated piezos is placed at a corner of said glass in a vertical orientation instead of horizontal orientation.

11. A haptic screen as claimed in claim 9, wherein each of said four vibrated piezos is placed at a corner of said glass in a crosswise orientation instead of horizontal orientation.

12. A haptic screen as claimed in claim 9, wherein each of said four vibrated piezos is placed at one side of the glass instead of its corners in said horizontal orientation.

13. A haptic screen, wherein said touch screen surface is configured to be tactically detectable, and wherein
each of said four piezos is placed at a corner of said glass in a horizontal orientation and vibrated by a sinusoidal wave of 290-320 Hz as a solution of an applicable equation if the spot touched by the user is at somewhere in the middle of two halves of the glass.

14. A haptic screen as claimed in claim 13, wherein each of said four vibrated piezos placed at a corner of said glass in a vertical orientation instead of horizontal orientation.

15. A haptic screen as claimed in claim 13, wherein each of said four vibrated piezos is placed at a corner of said glass in a crosswise orientation instead of horizontal orientation.

16. A haptic screen as claimed in claim 13, wherein each of said four vibrated piezos is placed at one side of the glass instead of its corners in said horizontal orientation.

17. (canceled)

18. (canceled)

19. (canceled)

20. (canceled)

21. A haptic screen comprising:
a display configured to display an image and a surface of which has been enabled to be vibration-simulated;
a glass attached at its pressed and vibrated sides;
a detection surface placed over the glass, which is an IR frame or similar or comprise a resistive, electromagnetic or capacitive film layer;
and at least four piezos which are vibrated at different frequencies and selected, depending on a spot to be vibrated on the glass, from the group consisting of:
four piezos placed at locations around the corners of glass in a horizontally oriented fashion,
four piezos placed at locations around the corners of glass in a vertically oriented fashion,
four piezos placed at locations around the corners of glass in a crosswise oriented fashion, and
four piezos placed at one side of glass in a horizontally oriented fashion.

22. A haptic screen as claimed in claim 21, wherein in order to generate the highest impact at the lowest amplitude, four piezos as included in one of the models of corner placement with horizontal orientation, corner placement with vertical orientation, corner placement with crosswise orientation and side placement with horizontal orientation are vibrated so as to create the highest impact on any spot over the glass with the lowest load (G) achievable through application of the following formula:
MÜ+KU=T_{GΦ}G
K=Kᵤᵤ−K_{uΦ} K_{ΦΦ}⁻¹K_{uΦ}^{T}
T_{GΦ}=−K_{uΦ} K_{ΦΦ}⁻¹

23. A haptic screen as claimed in claim 1, wherein said touch screen surface is configured to be tactically detectable and wherein each of said four piezos is placed at a corner of said glass in a horizontal orientation and vibrated by a sinusoidal wave of 100-120 Hz as a solution of an applicable equation if the spot touched by the user is on the central vertical axis of the glass.

24. A haptic screen as claimed in claim 1, wherein said display is selected from the group consisting of: CRT, LCD, LED or OLED display.

25. A haptic screen as claimed in claim 21, wherein said display is selected from the group consisting of: CRT, LCD, LED or OLED display.
